(19) United States
(12) Patent Application Publication
(10) Pub. No.: US 2026/0136844 A1
(43) Pub. Date: May 14, 2026

(54) WAFER-TO-WAFER DIRECT BONDING METHOD

(71) Applicant: COMMISSARIAT A L'ENERGIE ATOMIQUE ET AUX ENERGIES ALTERNATIVES, PARIS (FR)

(72) Inventors: Franck FOURNEL, GRENOBLE Cedex 09 (FR); Karine ABADIE, GRENOBLE Cedex 09 (FR); Laurent MICHAUD, GRENOBLE (FR)

(73) Assignee: COMMISSARIAT A L'ENERGIE ATOMIQUE ET AUX ENERGIES ALTERNATIVES, PARIS (FR)

(21) Appl. No.: 19/388,938

(22) Filed: Nov. 13, 2025

(30) Foreign Application Priority Data
Nov. 13, 2024 (FR) FR2412358

(51) Int. Cl. H01L 21/18; H01L 21/324; H01L 21/67

(52) U.S. Cl. CPC H10P 10/128; H10P 72/0402; H10P 95/90

(57) ABSTRACT

The invention relates to a method for directly bonding a first microelectronic device (100) on a second microelectronic device (200) comprising a provision of a first device having a first flat surface (110), and of a second device having a second flat surface (210), a treatment of at least first and second surfaces with a plasma gas comprising at least one first fluorinated gas, having an atomic percentage F of fluorine, a transfer of the first and second devices to a piece of bonding equipment, an immersion of the first and second surfaces in a bonding atmosphere (1) and a bonding of the first and second surfaces under the bonding atmosphere. The atomic percentage F of fluorine and the relative humidity RH are synergistically controlled, such that a bonding speed Vc is less than or equal to 15 mm/s and more specifically, less than 10 mm/s.

### TECHNICAL FIELD

The present invention relates to the assembly of microelectronic devices, in particular for 3D integration, more specifically, wafer-to-wafer direct bonding.

### PRIOR ART

With the aim of improving the densification of transistors in a microelectronic device, the advent of 3D integration appears as a promising solution, making it possible to utilise the third vertical dimension without necessarily making use of the miniaturisation of components. In doing so, an approach would be to superpose one transistor layer on another existing transistor layer. Another approach consists of powering the transistors from the rear face of the active zone, thus decreasing the dimensions of a unit cell. These two approaches can be achieved, thanks to wafer-to-wafer direct bonding. To have access to transistors from the rear face of the active zone, the device is often bonded to a support to enable the removal of the substrate on which the transistors are formed by tapering, for example, thus giving access to the transistors.

However, the wafer-to-wafer direct bonding step often induces distortions, which can complicate alignment during the following steps of the method, like for example, the formation of the power network by lithography, which requires a very accurate alignment. In addition, the residual constraints of the preceding steps on the wafers lead to additional challenges. Although the raw distortion is generally around 80 nm, it can be reduced around 10 nm after correction of the alignment of the wafers and of the fields of the chips by the equipment used in lithography. However, these values also exceed the strict requirements of sub-2nm nodes, therefore requiring additional optimisations.

There is therefore a need consisting of reducing the distortions during the bonding step, while guaranteeing a sufficiently high adherence energy to guarantee the integrity of the wafers until reconnection on the rear face in lithography. The bonding method activated by plasma containing fluorine is a technique used to create strong bonds, therefore a good adherence, during bonding, in particular for Si/Si bondings. The Wang et al. document (doi.org/10.1016/j.microrel.2011.09.005) describes a bonding method, also with other materials under a fluorinated plasma, such as oxides (SiO₂). This document demonstrates high bonding energies, of around 1.4 J/m² in surface energy, that is 2.8 J/m² in bonding energy for a SiO₂/SiO₂ bonding. However, this document does not deal with the problem of distortions during the bonding step.

The present invention aims to resolve at least some of the problems mentioned above.

### SUMMARY

To achieve this aim, according to an embodiment, a method for directly bonding a first microelectronic device on a second microelectronic device is provided, comprising the following steps:
a provision of a first microelectronic device having a first flat surface, and of a second microelectronic device having a second flat surface,
a treatment of at least one from among the first and second surfaces with a plasma gas comprising at least one first fluorinated gas, having an atomic percentage F of fluorine,
a transfer of the first and second devices to a bonding equipment,
an immersion of the first and second surfaces in a bonding atmosphere having a controlled relative humidity RH,
a bonding of the first and second surfaces disposed facing one another, using the bonding equipment under the bonding atmosphere, in which a partial adhesion of the first and second surfaces is initiated and propagates in the form of a bonding wave at a speed Vc, called bonding speed,
   the method being such that the atomic percentage F of fluorine during the treatment step, and the relative humidity RH during the bonding step, are synergistically controlled, such that the bonding speed Vc is less than or equal to 15 mm/s. And next, a preferred case, less than 10 mm/s.

Contrary to a prejudice which suggests increasing the adherence energy by performing a rapid bonding, the method described above makes it possible to slow down the propagation of the bonding wave, thanks to controlling the surface chemistry of the surfaces to be bonded and of the relative humidity RH of the bonding atmosphere. A decrease of the humidity of the bonding atmosphere associated with an increase of the concentration of the plasma gas in fluorine, make it possible to slow down the bonding wave. The slowing down of the bonding wave plays an important role in reducing distortions induces by direct bonding. These reduction of the bonding speed is achieved, while maintaining a good adherence between the surfaces of the devices, thanks to the increase of the atomic percentage F of fluorine in the plasma gas. Indeed, by choosing a suitable pair (F, RH), the method makes it possible to reach bonding speeds less than 15 mm/s and more preferably, less than 10 mm/s, which is relatively slow with respect to standard bonding speeds, which are around 20 to 50 mm/s. This reduced bonding speed, makes it possible to significantly reduce the distortions during bonding, and to reach sufficiently high bonding energies, which guarantees a good adherence of the two surfaces.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1 to 4 schematically illustrate, along a transverse cross-section in a plane xz, different steps of a method for directly bonding two microelectronic devices according to an example of an embodiment of the invention.

FIG. 5 schematically illustrates, along a transverse cross-section in a plane xz, a step of the method for directly bonding two microelectronic devices according to another example of an embodiment of the invention.

FIGS. 6 to 10 schematically illustrate, along a transverse cross-section in a plane xz, different steps of the method for directly bonding two microelectronic devices according to another example of an embodiment of the invention.

FIG. 11A represents a mapping showing the distortions due to a direct bonding of two wafers according to a method, different from that of the present invention.

FIG. 11B represents mappings showing the distortions due to a direct bonding of two wafers according to the method of the present invention.

FIG. 12 represents a graph showing the adherence energy as a function of the bonding speed for different cases of direct bonding of two wafers.

The drawings are given as examples, and are not limiting of the invention. They constitute principle schematic representations, intended to facilitate the understanding of the invention and are not necessarily to the scale of practical applications.

### DETAILED DESCRIPTION

Before starting a detailed review of embodiments of the invention, optional features are stated below, which can optionally be used in association or alternatively:

According to an example, the transfer of the first and second devices to the bonding equipment is done directly after the plasma gas treatment without passing through an intermediate cleaning step.

The direct transfer of devices to the bonding equipment, without passing through a cleaning step after the plasma treatment, makes it possible to further slow down the bonding speed, without widely decreasing the adherence energy.

According to an option, the plasma gas treatment is performed on each of the first and second surfaces. Preferably, the same plasma gas is used to treat each of the two surfaces; but, it is possible to use different plasma gases.

According to an example, the relative humidity RH is greater than or equal to 0% and less than 45%.

According to an example, the relative humidity RH is less than or equal to 2%, preferably less than or equal to 1%.

The bonding step is often carried out in a clean room, the relative humidity of which is around 45%. The present application proposes performing the bonding in an atmosphere which is less humid than that of a clean room, which makes it possible to significantly reduce the bonding speed Vc. However, the slowing down of the bonding wave is accompanied by a reduction of the adherence energy. In order to compensate for the adherence energy, the atomic percentage F of fluorine during the plasma treatment can be increased.

According to an example, the atomic percentage F of fluorine is greater than or equal to 0.4%.

According to an example, the atomic percentage F of fluorine is less than or equal to 4%.

The atomic percentage of fluorine F can be increased beyond the value reported in the Wang et al. document, which is around 0.4%. An atomic percentage of fluorine F=0.4% makes it possible to obtain an optimal adherence energy in the scope of the method of Wang et al. However, for such a value of F, the bonding speed Vc is not affected, and is around 30 mm/s, which is relatively rapid. A decrease of the relative humidity associated with an increase of the atomic percentage of fluorine beyond 0.4%, makes it possible to reduce the bonding speed, while guaranteeing a good adherence energy thanks to the presence of fluorine in the treatment of bonding surfaces by the fluorinated plasma.

According to an example, the bonding equipment comprises a bonding chamber in which the first (100) and second (200) devices are inserted during the transfer step, and the immersion of the first and second surfaces in the bonding atmosphere comprises an injection of a flux of a third so-called bonding gas in the bonding chamber, such that the bonding gas is confined in the bonding chamber thus forming the bonding atmosphere.

The bonding step being carried out in a chamber, makes it possible, on the one hand, to reduce the contaminants which can be present in the bonding atmosphere, and on the other hand, to best control the relative humidity in a restricted space.

According to an example, the immersion of the first and second surfaces in the bonding atmosphere comprises an injection of a flux of a third so-called bonding gas, such that the bonding gas fills at least one region between the first and second surfaces disposed facing one another, thus forming the bonding atmosphere.

According to an example, which the bonding gas consists of, or is a mixture comprising at least one of the following gases: He, CO₂, N₂, O₂, Ne, Ar, CF₄, SF₆, NF₃ and H₂. Using a short mean free path gas to form the bonding atmosphere makes it possible to slow down the bonding wave (for example, CO₂).

According to an example, the first gas consists of, or is a mixture comprising at least one of the following gases: SF₆, CF₄, NF₃ and F₂.

According to an example, the plasma gas comprises a second gas consisting of, or being a mixture comprising at least one of the following gases: N₂, O₂, Ar and He.

According to an example, the method further comprises a thermal treatment of the first and second surfaces before bonding, the treatment making it possible to carry the first and the second surfaces at a temperature greater than or equal to 20° C. and/or less than or equal to 150° C., preferably less than or equal to 50° C. Increasing the temperature of the surfaces before bonding makes it possible to slow down the bonding wave.

According to an example, the first device is a wafer comprising a first stack, said first stack comprising at least one transistor and being in contact with the first surface, and the second device is a wafer comprising a second stack, said second stack comprising at least one transistor and being in contact with the second surface.

This method makes it possible to assemble, by directly bonding two transistor layers along the third vertical direction, with the least distortions between the two layers, which improves the overall alignment of the two surfaces, and facilitates the post-bonding manufacturing steps.

According to an example, the first device is a wafer comprising a first stack on a substrate, said first stack comprising at least one transistor and being in contact with the first surface, the substrate being intended to be removed following bonding, and the second device is a wafer comprising at least one support layer in contact with the second surface.

This method also makes it possible to transfer by direct bonding on a support layer, a transistor layer formed on a substrate, to then remove the substrate and form a power network for transistors from the rear face of the stack. An advantage of the method resides in the fact that this transfer can be done by effectively reducing the distortions of the surfaces, which facilitates the post-bonding lithography steps, in particular, the alignment of the markers.

According to an example, at least one of the first and second surfaces is with the basis of a semiconductor material, an oxide, a metal, or also comprises at least one zone with the basis of an oxide and a zone with the basis of a metal or of a semiconductor.

The method not only enables a bonding of silicon surfaces, but also, the bonding of oxide surfaces, while reducing the distortions. Indeed, for an Si/Si hydrophobic bonding, the bonding speed is reduced, but this method makes it possible to bond oxide surfaces with a bonding speed which is even more reduced or equivalent.

In the scope of the present invention, a transfer and bonding method applied to the bonding of a wafer on a wafer is described. This method can extend to the bonding of one or more chips on a wafer or the bonding of a chip on a chip. This method is preferably intended for an industrial implementation, to transfer and bond a wafer on a wafer. It belongs to the field of direct bonding. This direct bonding can be a hybrid bonding. “Hybrid” means that the bonding surfaces are composed of at least two materials. “Direct” means that the bonding interface corresponds, after final bonding, directly to the two bonding surfaces, without there being a bonding layer, like a polymer glue, inserted between the two bonding surfaces. The direct bonding is also a spontaneous bonding, which therefore propagates all alone without external support. This is not, for example, thermocompression.

In the present application, a “wafer” typically means a substrate, comprising or carrying a plurality of chips. A wafer can have no components. A “chip” typically means an integrated circuit comprising microelectronic or optoelectronic components, or also electromechanical microsystems (MEMS). The alignment can be done with alignment marks, simply with the movement accuracy of the machine, or with the assistance of mechanical abutments, which use the edge of the substrates.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer covers at least partially the second layer by being either directly in contact with it, or by being separated from it by at least one other layer or at least one other element.

A layer can moreover be composed of several sublayers of one same material, or of different materials.

By a substrate, a layer, a device “with the basis” of a material M, this means a substrate, a layer, a device comprising this material M only, or this material M and optionally other materials, for example, alloy elements, impurities or doping elements.

The steps of the method mean, in the broad sense, the carrying out of some of the method and can optionally be carried out in several substeps. Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequencing of the phases of the method.

The dimensional values mean the manufacturing and measuring tolerances.

The terms “substantially”, “around”, “about” mean, when they relate to a value, “plus or minus 10%” of this value or, when they relate to an angular orientation “plus or minus 10°” of this orientation. Thus, a direction substantially normal to a plane means a direction having an angle of 90±10° with respect to the plane.

A preferably orthonormal system, comprising the axes x, y, z is represented in the accompanying figures.

The thickness of a layer or of the substrate is measured along a direction perpendicular to the surface, according to which this layer or this substrate has its maximum extension. The thickness is thus taken along a direction perpendicular to the main faces of the layer or of the substrate on which the different layers rest. More specifically, the thickness can be taken along the direction z.

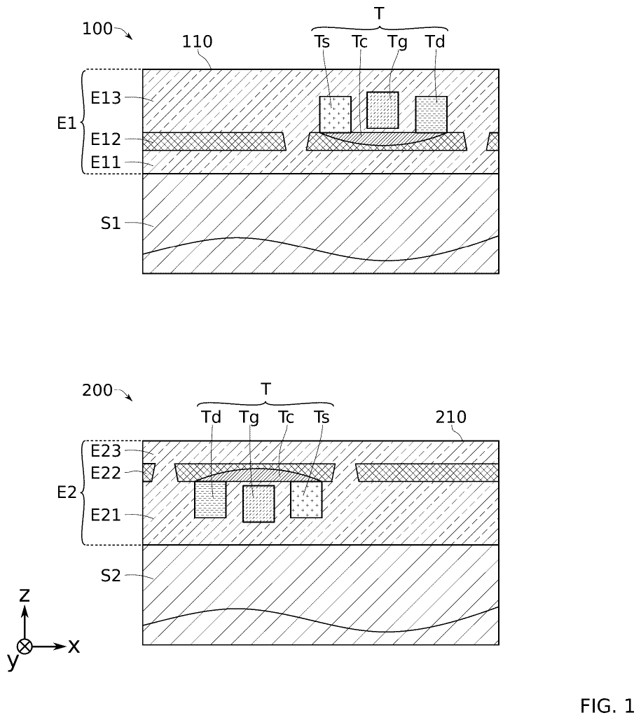

The method for assembling two microelectronic devices by direct bonding is now described in reference to FIGS. 1 to 4.

As illustrated in FIG. 1, the method comprises a provision of a first microelectronic device 100 and of a second microelectronic device 200. The first device 100 can comprise a first substrate S1 extending into a horizontal plane xy, defined by a direction x and a direction y perpendicular to the direction x. The first substrate S1 is surmounted by a first stack E1 of at least one layer along a direction z perpendicular to the directions x and y. The first device 100 has a first flat surface 110, called first bonding surface. This first surface 110 corresponds to the exposed face of the first stack E1.

The second device 200 can comprise a second substrate S2 extending into the plane xy, and surmounted by a second stack E2 of at least one layer along the direction z. The second device 200 has a second flat surface 210, called second bonding surface. This second surface 210 corresponds to the exposed face of the second stack E2.

The first 110 and second 210 bonding surfaces, are intended to be bonded to one another by direct bonding, in order to assemble the first 100 and second 200 devices along the direction z. Before the bonding step, the method comprises a treatment of the first 110 and second 210 bonding surfaces by a fluorinated plasma gas. The plasma gas comprises at least one first gas comprising fluorine. The plasma gas can comprise a second gas or a plurality of gases mixed with the first gas comprising fluorine. The plasma gas has an atomic percentage F of fluorine. This treatment of bonding surfaces by the fluorinated plasma gas, makes it possible to reduce the adhesion energy of direct bonding. The speed of the bonding wave is thus reduced. The treatment of the surfaces by fluorinated plasma makes it possible, on the contrary, to increase the adherence energy of the bonding surfaces after a consolidation annealing. This adherence energy depends on the concentration of the plasma gas in fluorine, or of the atomic percentage F of the plasma gas.

Following the treatment of the first 110 and second 210 bonding surfaces by fluorinated plasma, the method comprises a transfer of the first 100 and second 200 devices to a bonding equipment 20. The bonding equipment 20 makes it possible to handle the devices, to align them against one another, and to assemble them by direct bonding.

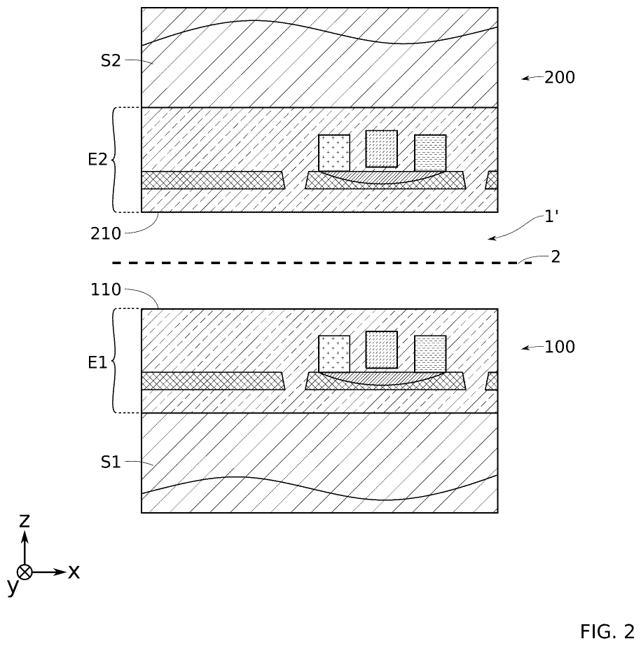

As illustrated in FIG. 2, the first 110 and second 210 surfaces are disposed facing one another, with respect to a bonding interface 2, preferably parallel to the plane xy. The alignment of the two surfaces 110, 210, can be done in planes parallel to the bonding interface 2 and disposed on either side of the bonding interface 2. The two bonding surfaces 110, 210, separated and disposed one facing, and the other before bonding, defining a region 1′.

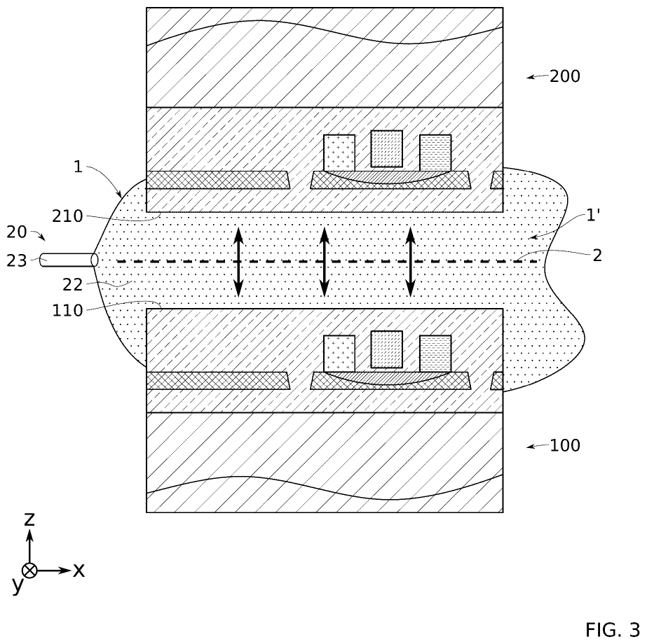

As illustrated in FIG. 3, before carrying out the bonding step, the method comprises an immersion of the first 110 and second 210 bonding surfaces in a bonding atmosphere 1. The bonding atmosphere 1 can be formed by injecting a flux of a third gas 22 called bonding gas, in particular in the region 1′, such that the bonding surfaces 110, 210, are immersed in this gas 22, thus forming the bonding atmosphere 1. The bonding equipment 20 can comprise at least one gas injector 23 connected to a bonding gas reservoir, and making it possible to inject the bonding gas 22. The gas injector 23 can be equipped with a first sensor and a valve, making it possible to monitor and adjust the flow rate of the bonding gas 22.

The bonding atmosphere 1 has a relative humidity referenced RH. The relative humidity RH of the bonding atmosphere 1 is controlled, preferably, before and along the

bonding step. Indeed, the bonding gas 22 injected into the region 1′, makes it possible to replace the air present in this region 1′, which generally contains humidity. Thus, by replacing air with bonding gas 22, which is preferably dry, the relative humidity RH of the bonding atmosphere 1 decreases progressively up to reaching a certain stable value before bonding. This RH value is preferably maintained fixed, until the bonding is ended.

The bonding equipment 20 can comprise, for example, a second sensor, such as a hygrometer, making it possible to measure the relative humidity RH of the bonding atmosphere 1. This second sensor can be connected to a control system, for example, which makes it possible to regularise the relative humidity RH in real time. This can be done by connecting the first sensor and the valve of the injector 23 to the control system, which makes it possible to have a feedback loop, in order to adjust the flow rate of bonding gas 22, as a function of the relative humidity RH measured in the bonding atmosphere 1.

This controlling of the relative humidity of the bonding atmosphere 1 makes it possible to form a bonding atmosphere 1, drier with respect to the ambient atmosphere, or the atmosphere of a clean room in which the direct bonding is typically done.

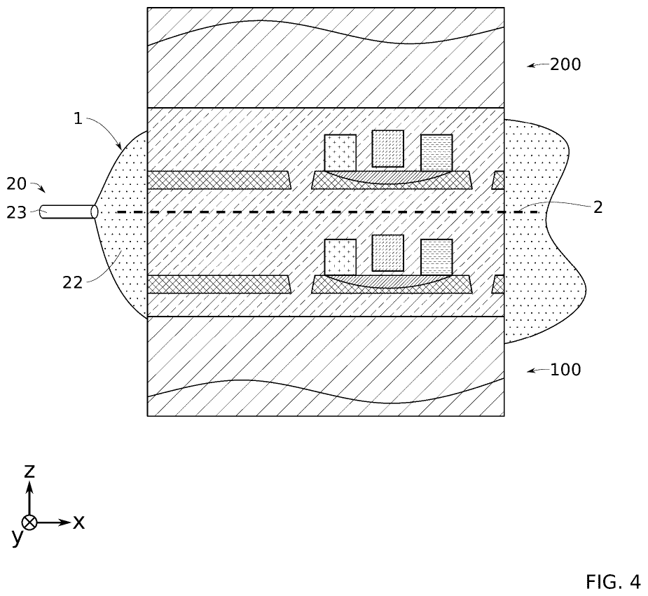

As illustrated in FIG. 4, the method comprises a bonding of the first 110 and second 210 surfaces by moving them closer to one another at the bonding interface 2 with a distance less than 500 μm or more preferably less than 100 μm even 50 μm. It is also possible to just let the surface fall from the top on the one below. The air film of the bonding atmosphere which is trapped between the surfaces, automatically ensures a separation with a distance less than around 100 μm after a few seconds, even below 10 μm. The bonding interface 2 constitutes a plane which comprises both the first 110 and second 210 surfaces. The bonding of the two surfaces 110, 210, is done under the bonding atmosphere 1. When the two surfaces 110, 210, are close to one another, such as described above, a partial adhesion is initiated to at least one zone in the plane of the bonding interface 2, like the centre of a bonding surface, for example. This initiation is done by putting the surfaces in physical contact locally. This can be done by means of a bonding tip. This partial adhesion then propagates radially in the plane of the bonding interface 2 from the centre to the edges of the bonding surfaces, in the form of a wave known under the bonding wave and this, even if the bonding tip is removed. It is in relation to this, that spontaneous bonding is referred to. There is a self-propagation of the adhesion. In the case where the surface of the top is simply released above that of the bottom one, and that the separation is ensured by an air film, it is possible to leave gravity to obtain spontaneous bonding. However, the initiation point is thus not controlled, which can further be multiple. This bonding wave is characterised by a bonding speed Vc which affects the bonding quality. The more rapid the bonding wave is, i.e. the greater the bonding speed Vc is, the more distortions due to bonding there are. The distortions are mechanical deformations along the bonding interface. The distortions resulting from a direct bonding are generally random and difficult to compensate for by digital models during an alignment of the markers to perform a lithography, for example.

By reducing the bonding speed Vc, the distortions due to bonding are significantly reduced. The dry bonding atmosphere 1 makes it possible to reduce the bonding speed. However, this reduction of the bonding speed is generally accompanied by a reduction of the adherence energy of the bonding surfaces, which is not desirable. A good adherence of the bonding surfaces is high, as it makes it possible to guarantee a good mechanical stability of the assembly, in particular, during post-bonding manufacturing steps.

To compensate for the weakness of the adherence energy, the atomic percentage F of fluorine is reduced during the step of treating by fluorinated plasma, synergistically to the reduction of relative humidity RH of the bonding atmosphere 1 during the bonding step. By varying these two parameters, a pair (F, RH) can be chosen, so as to slow down the bonding speed considerably during bonding, while guaranteeing a good adherence of the bonding surfaces. Therefore, thanks to this synergic control of the F and RH parameters, a bonding speed Vc less than or equal to 15 mm/s, and more preferably, less than 10 mm/s is obtained. Such a bonding speed Vc makes it possible to reduce distortions due to bonding. On the other hand, thanks to this synergic control of the F and RH parameters, the bonding makes it possible to obtain an adherence energy which is sufficiently high for the production of assemblies of microelectronic devices.

The atomic percentage F of fluorine present in the plasma gas, can be greater than or equal to 0.4%. For a value of F which is close to 0.4%, the effect of the concentration of fluorine in plasma on the bonding speed is negligeable. In this case, the relative humidity RH of the bonding atmosphere must be highly decreased. In order to affect, in particular, reduce, the bonding speed Vc, the atomic percentage F is advantageously increased beyond 0.4%. A high increase of F can be accompanied by a moderate decrease of RH. Similarly, a high decrease of RH can be accompanied by a moderate increase of F. Preferably, the atomic percentage F is less than or equal to 4%. Indeed, beyond 4%, the bonding of the two surfaces 110, 210 is compromised.

The relative humidity RH of the bonding atmosphere 1 during the bonding step is advantageously strictly less than 45%. The relative humidity RH of the bonding atmosphere 1 can be ideally zero, or slightly greater than 0% during the bonding step. According to an example, the relative humidity RH is controlled, such that it is less than or equal to 10%, preferably less than or equal to 2%, more preferably, less than or equal to 1%.

A complementary approach to the joint variation of the F and RH parameters, making it possible to reduce the bonding speed Vc, consists of omitting a step of cleaning, in particular chemical, the bonding surfaces 110, 210 following the treatment of the surfaces by fluorinated plasma. Indeed, according to this example of an embodiment, the transfer of the first and second devices 100, 200, to the bonding equipment 20 is done directly after the plasma treatment. This transfer can be done under the atmosphere of the clean room, for example.

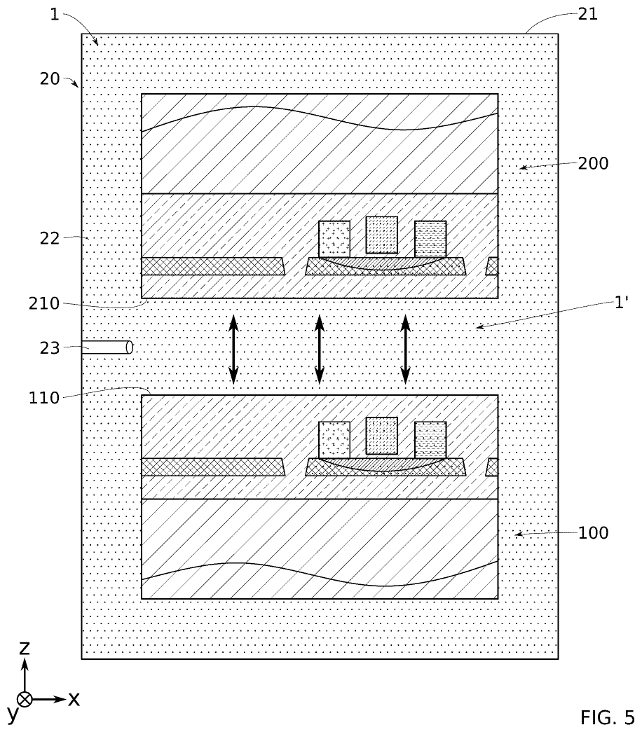

As illustrated in FIGS. 3 and 4, according to a variant, the immersion of the first 110 and second 210 surfaces in the bonding atmosphere 1, can be done in a non-confined space, i.e. a space which is not strictly closed like a bonding chamber. According to this variant, the gas injector 23 can be disposed at the region 1′, such that the injected bonding gas 22, fills at least the region 1′ thus forming the bonding atmosphere 1. The bonding atmosphere 1 or the bonding gas 22 can extend beyond the region 1′, as the bonding surfaces 110, 210, and the region 1′ are immersed in the bonding gas. The bonding atmosphere can include some or all of the first and second devices. According to this variant, the bonding gas 22 is not necessarily confined. The bonding can be done under a bonding atmosphere 1 formed locally by the bonding gas, within a clean room, for example. As illustrated in FIG. 5, according to another variant, the bonding equipment 20 can comprise a bonding chamber 21. According to this variant, following the treatment of the bonding surfaces by plasma, the devices 100, 200, are inserted into the bonding chamber 21 such that the chamber 21 fully contains the devices 100, 200, thus forming a confined space. The injector 23 of the bonding gas 22 is disposed inside this bonding chamber 21. The injector 23 can be disposed at the region 1′, or in another location inside the bonding chamber 21. The immersion of the bonding surfaces 110, 210, in the bonding atmosphere 1, thus comprises an injection of the bonding gas 22 inside the bonding chamber 21 to form the bonding atmosphere 1. According to an example, the ambient air confined in the bonding chamber before the formation of the bonding atmosphere 1, can be removed from the bonding chamber progressively during the injection of the bonding gas 22, which replaces it, or completely before the injection of the bonding gas 22. The bonding gas 22 extends into the entire bonding chamber 21, and in particular in the region 1′ between the bonding surfaces 110, 210. The use of a bonding chamber 21 makes it possible to decrease the presence of contaminants during bonding. This is advantageous in the scope of a bonding method in which the cleaning of the surfaces after the plasma treatment is not done.

As illustrated in FIGS. 1 to 5, the method described above makes it possible to assemble, for example, two wafers by direct bonding. The first device 100 can be a first wafer comprising a first substrate S1 on which a first stack E1 is formed. The first stack E1 can comprise a first silicon oxide-based support layer E11 called “BOX” (buried oxide), surmounted by a first silicon-based active layer E12, for example, comprising at least one, preferably more transistors T. The stack E1 can further comprise a SiO₂-based protective layer E13, the exposed face of which is no other than the first bonding surface 110. Each transistor T comprises a source Ts, a drain Td and a gate Tg which can be integrated in the protective layer E13, and a channel Tc integrated in the active layer E12.

The second device 200 can be a second wafer comprising a second substrate S2, on which a second stack E2 is formed. The stack E2 can also comprise a second silicon oxide (BOX)-based support layer E21, surmounted by a second Si-based active layer E22, comprising at least one, preferably more transistors T. The stack E2 can further comprise an SiO₂-based protective layer E23, the exposed face of which is no other than the second bonding surface 210. Each transistor T comprises a source Ts, a drain Td and a gate Tg which can be integrated in the protective layer E23, and a channel Tc integrated in the active layer E22.

As illustrated in FIG. 4, these two wafers can be assembled by direct bonding along the direction z, using the method of the present invention. This assembly makes it possible to increase the density of the transistors, by vertically superposing two active layers comprising transistors. An advantage of this method is to perform the bonding with less distortions, guaranteeing a better alignment between the two wafers, which makes it possible to facilitate the post-bonding methods, and to obtain microelectronic assemblies on the industrial scale.

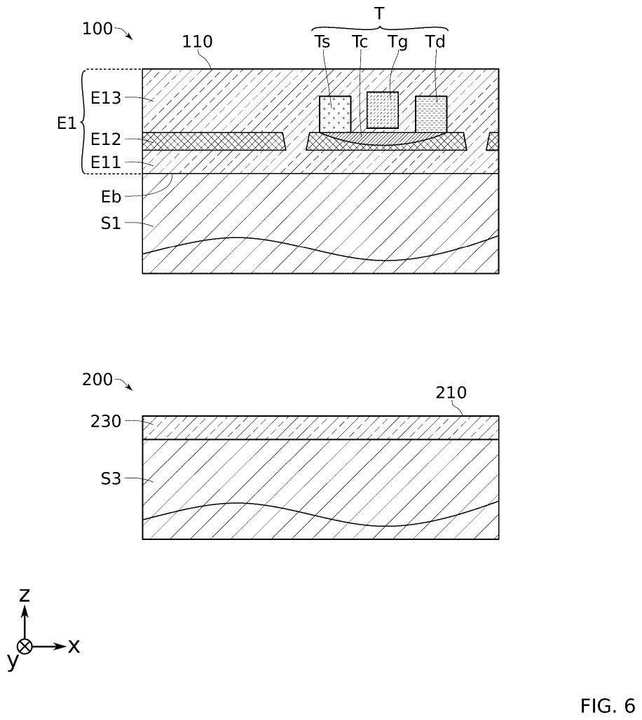

FIGS. 6 to 10 illustrate another example of an application of the method of the present invention. According to this example, as illustrated in FIG. 6, the first device 100 can be a first wafer, identical to that described above. The second device 200 can be a third so-called support (carrier) wafer, comprising a third substrate S3 and a third SiO₂-based support layer 230, for example, formed on the substrate S3. The third support layer 230 has an exposed face which is no other than the second bonding surface 210. The third support layer 230 cannot comprise electronic components or active sublayers, and only be used for supporting the first wafer.

The first wafer can be transferred onto the support wafer by direct bonding, using the method of the present invention.

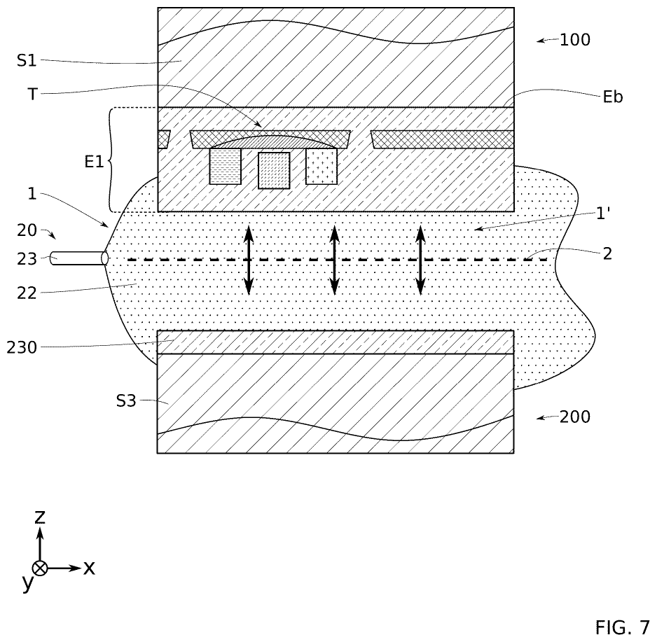

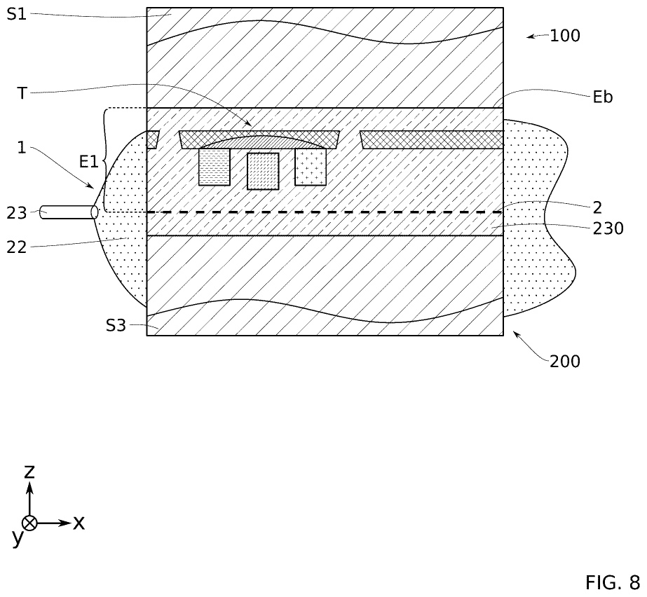

As illustrated in FIG. 7, following the treatment of the bonding surfaces by fluorinated plasma, the first wafer is returned and aligned relative to the support wafer, such that the first 110 and second 210 bonding faces are disposed facing one another. The bonding faces 110, 210, are then immersed in the bonding atmosphere 1, to then be put in contact during the bonding step, such as illustrated in FIG. 8. The present method makes it possible to transfer the wafer comprising the transistors, by limiting the distortions of the first bonding face due to direct bonding.

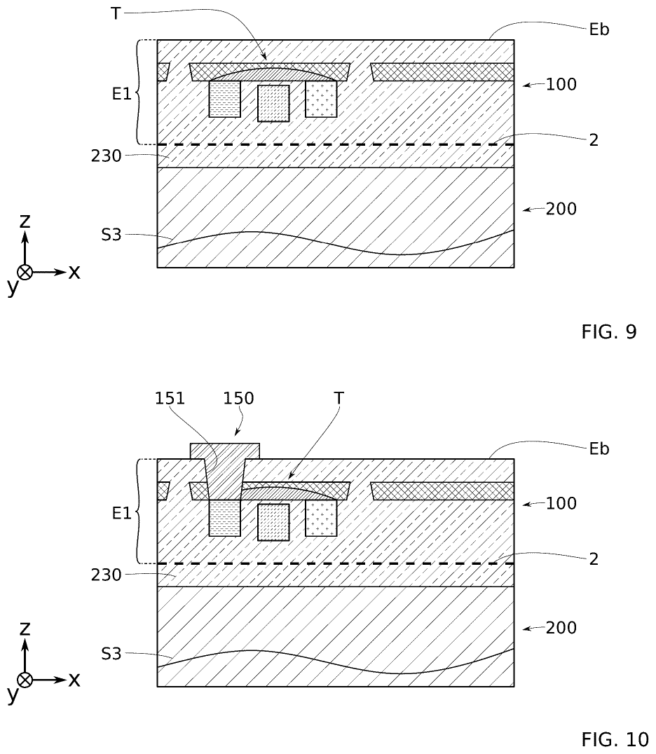

Transferring the first wafer onto the support wafer, makes it possible to handle a rear face Eb of the stack E1. For that, as illustrated in FIG. 9, the substrate S1 can be removed, following the bonding of the two wafers, thus making it possible to expose the rear face Eb of the stack E1. This facilitates access to the layers of the stack E1, in particular the active layer E12, without needing to pass through the substrate S1, which can have a significant thickness of around several hundreds of micrometres. The substrate can be removed, for example, by a chemical etching and/or by abrasion.

As illustrated in FIG. 10, following the removal of the substrate, a power network 150 can be manufactured on the rear face Eb of the stack E1. This power network is known under the term, “Back-Side Power Delivery Network” (BS-PDN) because it is formed on the rear face. The power network 150 can comprise, for example, vias 151 passing through the stack E1 to the sources Ts, drains Td, and gates Tg of the transistors T. The formation of the power network on the rear face of the stack, makes it possible to save lateral space, i.e. in the plane xy, and consequently to increase the density of transistors within the stack. Reducing distortions using the method of the present invention, makes it possible to facilitate the formation of the power network 150, which can involve lithography and alignment steps using premanufactured markers in the stack E1.

In the examples described above, the materials of the two bonding surfaces 110, 210, are oxide-based, in particular, SiO₂-based. The method makes it possible to bond oxide surfaces, for example SiO₂/SiO₂, with a bonding speed Vc less than the bonding speed of two hydrophobic Si/Si surfaces. The direct bonding according to this method is not limited to the SiO₂-based surfaces 110, 210, and can be done with bonding surfaces with the basis of other oxides, nitrides, semiconductors or metals. As an example, at least one of the bonding surfaces 110, 210, can be: Si3N4-, SiCN—, Al₂O₃—, TaN—, TiN—, Si—, Ge—, Ti—, Ni—, Cu—, Al—, Ta-based, etc. The bonding can be a hybrid bonding, with bonding surfaces comprising regions of different materials, for example oxide or nitride regions, and metal or semiconductor regions.

The first gas present in the plasma and comprising fluorine can be SF₆, CF₄, NF₃ or F₂, another gas comprising fluorine or a mixture of several gases comprising fluorine. The second gas present in the plasma can be a gas with no fluorine, for example, N₂, O₂, Ar, He, etc. The second gas can also be a mixture of several gases. The first and second gas forming the plasma, are chosen, so as to be adapted for the formation of a plasma.

The bonding gas 22 forming the bonding atmosphere 1, can be chosen from among the following gases: He, CO₂, N₂, O₂, Ne, Ar, CF₄, SF₆, F₂ and H₂. The bonding gas 22 can also be a mixture of several gases. Preferably, the bonding gas is chosen so as to have a short mean free path, which also reduces the speed of the bonding wave (for example, CO₂). Using helium, neon or hydrogen as a bonding gas makes it possible to reduce the formation of defects known as “spikes” which result from the bonding, and which are typically observed at the periphery of the final structure (generally, in the form of a circular platelet).

According to an example, the method can further comprise, a step of thermally treating the bonding surfaces 110, 210, before bonding them. This thermal treatment can be done before or after the transfer of the bonding surfaces to the bonding equipment 20. This thermal treatment can be implemented at a temperature greater than or equal to 20° C. and/or less than or equal to 150° C., and preferably less than or equal to 50° C. According to a preferable example, the thermal treatment is done at a temperature of between 20° C. and 50° C. If the thermal treatment is done before the transfer to the bonding equipment, it is necessary that the time between this treatment and the bonding, guarantees that the temperature of the surfaces, at the time of the bonding, that is less than or equal to 150° C. and preferably between 20° C. and 50° C.

A particular, non-limiting example of the application of the method is described below. Two wafers to be bonded having a diameter of 300 mm, comprising thermal oxide protective layers, 100 nm thick, are provided. The bonding surfaces of these wafers are therefore thermal oxide-based. The bonding surfaces are then cleaned during a preliminary cleaning with ozonated water, obtained by using deionised water with ozone, dissolved at a concentration of 14 ppm (parts per million), equivalent to 14 mg/L. The bonding surfaces are then rinsed with deionised water. The bonding surfaces are then treated by an APM (Ammonium Hydroxide-Hydrogen Peroxide Mixture) treatment, by using a solution composed of three main components, namely: ammonium hydroxide, hydrogen peroxide and deionised water, the ratio of the three components being 1-1-5 at 70° C. in the cleaning solution. The bonding surfaces are then etched very lightly in a hydrofluoric (HF) acid at a mass concentration of 0.1% for 30 s, then rinsed again with deionised water. Each of the preceding preliminary cleaning substeps can last around 10 minutes (except for that of HF).

Following the preliminary cleaning of the bonding surfaces, the wafers are introduced in a piece of EVG®850 LT equipment. The bonding surfaces are then cleaned a second time, using a Megpie® device, operating at 90 W and at 30 RPM (revolutions per minute) for one minute. This second cleaning uses a 2% ammoniac solution in deionised water. This makes it possible to effectively remove the particle contaminants from the bonding surfaces.

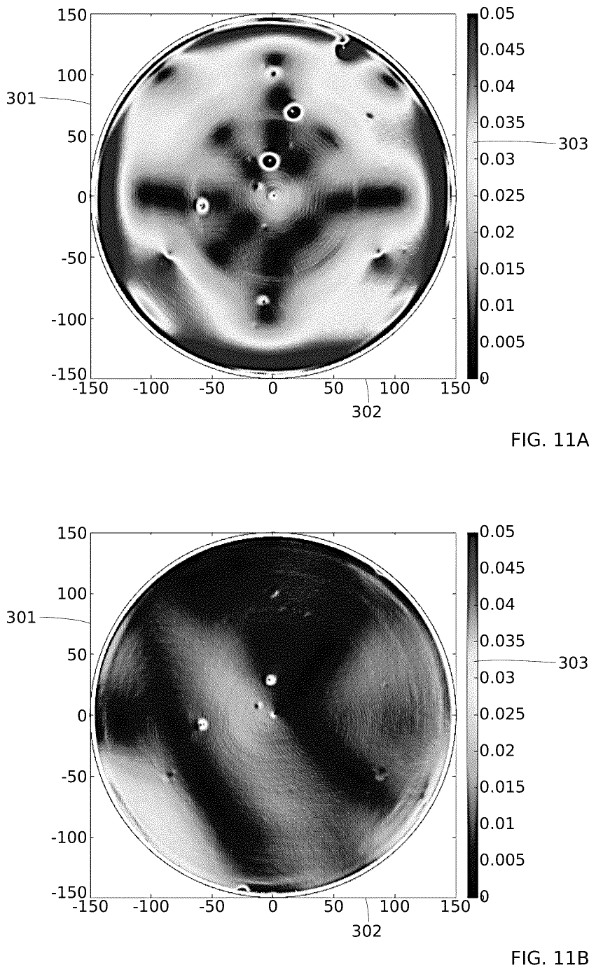

The bonding surfaces are then treated by fluorinated plasma comprising a first CF₄ gas with an atomic percentage F=0.4% and a second oxygen gas. The fluorinated plasma treatment can be done at frequencies of 47 KHz and of 347 KHz, and can last around 15 seconds. The two wafers are then transferred directly to the bonding chamber, by passing through the atmosphere of the clean room, characterised by a relative humidity of 45% and an ambient temperature of 21° C. The bonding atmosphere is then formed by injecting an He bonding gas until reaching a relative humidity RH of the bonding chamber less than 2%. The bonding of the two surfaces is then implemented under the dry bonding atmosphere. The bonding can be initiated by a localised pressure, preferably at the centre of the wafers, which can be around 3500 mN. The bonding wave propagates from the centre at a bonding speed Vc less than 15 mm/s and more preferably, less than 10 mm/s. FIGS. 11A and 11B, illustrate mappings of displacements in the plane (IPD - “in-plane displacement”) obtained using interferometric analyses of the assemblies obtained by direct bonding. These mappings represent a footprint of the deformations of the wafers due to direct bonding. FIG. 11A represents an IPD mapping of an assembly obtained by direct

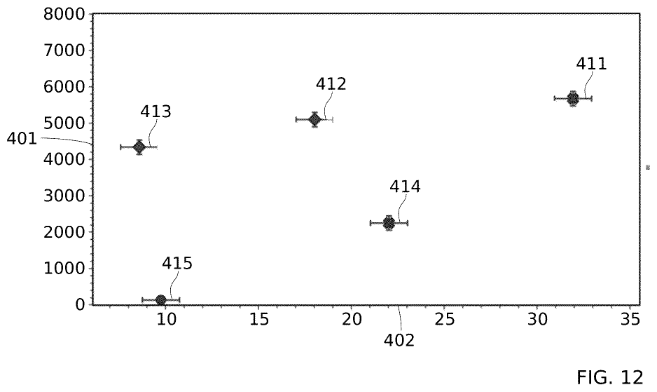

bonding of two wafers under standard conditions, in particular with a standard bonding speed (of around 30 mm/s). The x 302 and y 303 axes, represent the distance in millimetres (mm) from the centre of the wafers along the directions x and y, respectively. The colour scale 303 represents the post-bonding deformations of the wafers measured in micrometres along a direction z. FIG. 11B represents an IPD mapping of an assembly obtained by direct bonding of two wafers according to the particular example described above, in particular for a reduced bonding speed, less than 15 mm/s and more preferably, less than 10 mm/s. Comparing two mappings clearly shows the significant reduction of the distortions resulting from a direct bonding at a reduced bonding speed. This result proves the effectiveness of a bonding of surfaces treated by a fluorinated plasma and bonded under a dry atmosphere, in the reduction of distortions. FIG. 12 illustrates a graph in which the x-axis 401 represents the bonding speed Vc measured in mm/s, and the y-axis 402 represents the adherence energy measured in mJ/m² after an annealing at 300° C. In this graph, different points 411 to 415 are classified. These points represent the adherence energies obtained for different bonding speeds, during different cases of direct bonding of wafers. The points 414 and 415 in the lower part of the graph correspond to direct bondings performed without treatment of the surfaces with fluorinated plasma and in a standard bonding atmosphere (RH between 45% and 50%). The

adherence energy obtained for these two cases is not high enough, as the bonding surfaces have not been treated by fluorinated plasma before bonding. The case 415 corresponds to a bonding of hydrophobic surfaces. For hydrophobic bonding surfaces, the bonding speed is relatively low (˜10 mm/s). The points 411, 412 and 413 in the upper part of the graph correspond to direct bondings of surfaces which have undergone a fluorinated plasma treatment. The case 411 corresponds to a direct bonding of two wafers for F₄₁₁=0.4 and for RH₄₁₁˜50%, leading to an optimal adherence energy of around 5800 mJ/m² and to a high bonding speed of around 32mm/s. The case 412 corresponds to a direct bonding having the same parameters as the case 411, i.e. F₄₁₂=0.4 and for RH₄₁₂˜50%, in which the bonding surfaces have not been cleaned after the fluorinated plasma treatment. The omission of the cleaning of the bonding surfaces after the fluorinated plasma treatment makes it possible to decrease the bonding speed, up to almost 18 mm/s. However, this decrease of Vc is accompanied by a slight decrease of the adherence energy. Finally, the case 413 corresponds to a bonding according to the method of the present application, in which the surfaces have been treated with a plasma with F₄₁₃=0.4% and bonded under a dry atmosphere having a relative humidity RH₄₁₃˜0%. For this latter case, the bonding speed is reduced to almost 9 mm/s and the adherence energy is around 4200 mJ/m², which is sufficient to obtain a good adherence of the surfaces, thus showing the effectiveness of the present direct bonding method.

Below, an example of values being able to be used is given, preferably combined, to implement the invention, without a limiting character:
Atomic concentration of F in the plasma: 4%
Bonding atmosphere 40% RH
Speed of the bonding wave 6 mm/s
Bonding energy: 1900 mJ/m² at 100° C. (which represents a very good result for this temperature).

The invention is not limited to the embodiments described above and extends to all the embodiments covered by the invention. Different particular examples of the direct bonding method have been described. Other variants of embodiments are possible, for example, by combining features described above, without deviating from the principle of the present invention. Furthermore, the features described relative to an aspect of the invention can be combined with another aspect of the invention.

1. A method for directly bonding a first microelectronic device on a second microelectronic device comprising the following steps:
a provision of a first microelectronic device having a first flat surface and of a second microelectronic device having a second flat surface
a treatment of at least one from among the first and second surfaces with a plasma gas comprising at least one fluorinated gas, having an atomic percentage F of fluorine,
a transfer of the first and second devices to a bonding equipment,
an immersion of the first and second surfaces in a bonding atmosphere having a controlled relative humidity RH,
a bonding of the first and second surfaces disposed facing one another, using the bonding equipment under the bonding atmosphere, in which a partial adhesion of the first and second surfaces is initiated and propagates in the form of a bonding wave at a speed Vc called bonding speed,
wherein the atomic percentage F of fluorine during the treatment step, and the relative humidity RH during the bonding step, are synergistically controlled, such that the bonding speed Vc is less than or equal to 15 mm/s.

2. The direct bonding method according to claim 1, wherein the transfer of the first and second devices to the bonding equipment is done directly after the plasma gas treatment without passing through an intermediate cleaning step.

3. The direct bonding method according to claim 1, wherein the plasma gas treatment is performed on each of the first and second surfaces with one same plasma gas.

4. The direct bonding method according to claim 1, wherein the relative humidity RH is greater than or equal to 0% and less than 45%.

5. The direct bonding method according to claim 4, wherein the relative humidity RH is less than or equal to 2%.

6. The direct bonding method according to claim 1, wherein the atomic percentage F of fluorine is greater than or equal to 0.4%.

7. The direct bonding method according to claim 1, wherein the atomic percentage F of fluorine is less than or equal to 4%.

8. The direct bonding method according to claim 1, wherein:
the bonding equipment comprises a bonding chamber in which the first and second devices are inserted during the transfer step, and
the immersion of the first and second surfaces in the bonding atmosphere comprises an injection of a flux of a third gas called bonding gas into the bonding chamber, such that the bonding gas is confined in the bonding chamber, thus forming the bonding atmosphere.

9. The direct bonding method according to claim 1, wherein the immersion of the first and second surfaces in the bonding atmosphere comprises an injection of a flux of a third gas called bonding gas, such that the bonding gas fills at least one region between the first and second surfaces disposed facing one another, thus forming the bonding atmosphere.

10. The direct bonding method according to claim 8, wherein the bonding gas consists of, or is a mixture comprising at least one of the following gases: He, CO₂, N₂, O₂, Ne, Ar, CF₄, SF₆, NF₃, F₂ and H₂.

11. The direct bonding method according to claim 1, wherein the first gas consists of, or is a mixture comprising at least one of the following gases: SF₆, CF₄, NF₃ and F₂.

12. The direct bonding method according to claim 1, wherein the plasma gas comprises a second gas consisting of, or being a mixture comprising at least one of the following gases: N₂, O₂, Ar and He.

13. The direct bonding method according to claim 1, further comprising a thermal treatment of the first and second surfaces before bonding, the treatment makes it possible to carry the first and second surfaces at a temperature greater than or equal to 20° C. and/or less than or equal to 150°C.

14. The direct bonding method according to claim 1, wherein:
the first device is a wafer comprising a first stack, said first stack comprising at least one transistor and being in contact with the first surface and
the second device is a wafer comprising a second stack, said second stack comprising at least one transistor and being in contact with the second surface.

15. The direct bonding method according to claim 1, wherein:
the first device is a wafer comprising a first stack on a substrate, said first stack comprising at least one transistor and being in contact with the first surface the substrate being intended to be removed following the bonding, and
the second device is a wafer comprising at least one support layer in contact with the second surface.

16. The direct bonding method according to claim 1, wherein at least one of the first and second surfaces is with the basis of a semiconductor material, or an oxide, or a nitride, or a metal, or also comprises at least one zone with the basis of an oxide or a nitride and a zone with the basis of a metal or a semiconductor.

17. The direct bonding method according to claim 9, wherein the bonding gas consists of, or is a mixture comprising at least one of the following gases: He, CO₂, N₂, O₂, Ne, Ar, CF₄, SF₆, NF₃, F₂ and H₂.
